(19) United States
(12) Patent Application Publication
(10) Pub. No.: US 2026/0255786 A1
(43) Pub. Date: Aug. 27, 2026

(54) LIGHT-EMITTING ELEMENT AND METHOD FOR MANUFACTURING SAME, AND DISPLAY DEVICE AND METHOD FOR MANUFACTURING SAME

(71) Applicant: Sharp Display Technology Corporation, Kameyama City, Mie (JP)

(72) Inventors: JUN SAKUMA, Sakai City, Osaka (JP); YASUSHI ASAOKA, Sakai City, Osaka (JP); Sentaro KIDA, Sakai City, Osaka (JP); Takahiro ADACHI, Sakai City, Osaka (JP); Kota ADACHI, Sakai City, Osaka (JP)

(21) Appl. No.: 19/163,549

(22) PCT Filed: Mar. 9, 2023
(86) PCT No.: PCT/JP2023/009025

§ 371 Date: Sep. 9, 2025

(51) Int. Cl. H10K 50/16; H10H 20/01; H10H 20/816; H10H 29/01; H10K 50/15; H10K 59/12; H10K 59/35; H10K 71/60

(52) U.S. Cl. CPC H10K 50/16; H10H 20/011; H10H 20/816; H10H 29/012; H10H 29/032; H10K 50/15; H10K 59/1201; H10K 59/351; H10K 71/60

(57) ABSTRACT

A light-emitting element includes an anode, an EML, an ETL, and a cathode. The ETL contains a metal oxide and includes a first area and a second area that exhibits an oxygen vacancy concentration higher than an oxygen vacancy concentration of the first area.

### TECHNICAL FIELD

The present disclosure relates to light-emitting elements and methods for manufacturing the light-emitting elements and also to display devices and methods for manufacturing the display devices.

### BACKGROUND ART

Patent Literature 1 discloses a display device including a plurality of light-emitting elements each of which includes, for example, a hole transport layer and an electron transport layer both formed as a common film that is common to a red pixel, a green pixel, and a blue pixel and that extends over a bank covering an edge of a pixel electrode of the light-emitting element.

Such light-emitting elements and display devices can be manufactured by a short process and with good yields because there is no need to form, for example, a different hole transport layer and a different electron transport layer individually for each pixel.

### CITATION LIST

### Patent Literature

Patent Literature 1: US Patent Application Publication No. 2013/0043498

### SUMMARY

### Technical Problem

However, the light-emitting elements and display devices present difficulty in forming uniform films in the vicinity of the bank and exhibit a lower luminous efficiency in regions in the vicinity of the bank where the film formed is not uniform than in regions where the film formed is uniform.

In addition, the light-emitting element includes a light-emitting layer containing light-emitting materials each of which emits at least one of red light, green light, and blue light, which are the three primary colors, and the light-emitting materials are applied individually for each pixel. The regions above the bank where no light-emitting layer is provided exhibit a zero luminous efficiency because there is no light-emitting layer provided therein. In addition, those regions where there is provided no electrode in the light-emitting element and those regions where there is provided no bank in the light-emitting element are so far away in distance from the electrode as to reduce charge injection efficiency, which in turn reduces luminous efficiency.

The inventors of the disclosure have studied and found that the electric current that flows in these regions where luminous efficiency is low (hereinafter, may be referred to as the “excess current”) can cause a decrease in the luminous efficiency, such as the external quantum efficiency, of the light-emitting element.

The present disclosure has been made in view of these issues and has an object to provide a light-emitting element that enables relatively reducing excess current that flows in regions where luminous efficiency is low and that exhibits a high luminous efficiency such as external quantum efficiency and a method for manufacturing such a light-emitting element and also to provide a display device including such a light-emitting element and a method for manufacturing such a display device.

### Solution to Problem

To address the issues, the present disclosure, in one aspect thereof, is directed to a light-emitting element including: a first electrode and a second electrode; a light-emitting layer provided between the first electrode and the second electrode; and a charge transport layer provided between the first electrode and the light-emitting layer, wherein the charge transport layer contains a metal oxide and includes a first area and a second area that exhibits a higher oxygen vacancy concentration than does the first area.

To address the issues, the present disclosure, in one aspect thereof, is directed to a display device including a plurality of pixels each including the light-emitting element of an aspect of the present disclosure.

To address the issues, the present disclosure, in one aspect thereof, is directed to a method for manufacturing a light-emitting element including: a first electrode and a second electrode; a light-emitting layer provided between the first electrode and the second electrode; and a charge transport layer provided between the first electrode and the light-emitting layer, the method including: a charge-transport-layer-film-formation step of forming a charge transport layer containing a metal oxide as the charge transport layer; and a light-exposure step of forming, in a part of the charge transport layer, a second area that exhibits a higher oxygen vacancy concentration than does a first area that is a non-exposed area of the charge transport layer, by exposing the part of the charge transport layer to light to increase oxygen vacancies in an exposed area.

To address the issues, the present disclosure, in one aspect thereof, is directed to a method for manufacturing a display device including a plurality of pixels each including a light-emitting element, the method including a light-emitting-element-manufacturing step of manufacturing the light-emitting elements by the method for manufacturing the light-emitting element of an aspect of the present disclosure.

### Advantageous Effects of Disclosure

The present disclosure can provide a light-emitting element that enables relatively reducing excess current that flows in regions where luminous efficiency is low and that exhibits a high luminous efficiency, for example, a high external quantum efficiency and a method for manufacturing such a light-emitting element and can also provide a display device including such a light-emitting element and a method for manufacturing such a display device.

### BRIEF DESCRIPTION OF DRAWINGS

FIG. 1 is a schematic cross-sectional view of an example of a light-emitting element in accordance with Embodiment 1.

FIG. 2 is a plan view of an anode, a bank, and an electron transport layer in the light-emitting element shown in FIG. 1, as viewed from above the electron transport layer.

FIG. 3 is a schematic cross-sectional view of an example of a relationship between a light-emitting region and a non-light-emitting region and a first area and a second area in the light-emitting element in accordance with Embodiment 1.

FIG. 4 is a schematic cross-sectional view of another example of a relationship between a light-emitting region and a non-light-emitting region and a first area and a second area in the light-emitting element in accordance with Embodiment 1.

FIG. 5 is a schematic cross-sectional view of yet another example of a relationship between a light-emitting region and a non-light-emitting region and a first area and a second area in the light-emitting element in accordance with Embodiment 1.

FIG. 6 is a flow chart representing an example of a method for manufacturing the light-emitting element shown in FIG. 1.

FIG. 7 is a schematic cross-sectional view of an example of a structure of a major part of a display device in accordance with Embodiment 2.

FIG. 8 is a schematic cross-sectional view of an example of a structure of a major part of a display device in accordance with Embodiment 3.

FIG. 9 is a flow chart representing an example of a method for manufacturing a light-emitting element in the display device shown in FIG. 8.

FIG. 10 is a schematic cross-sectional view of an example of a structure of a major part of a display device in accordance with Embodiment 4.

FIG. 11 is a flow chart representing an example of a method for manufacturing a light-emitting element in the display device shown in FIG. 10.

FIG. 12 is a schematic cross-sectional view of an example of a structure of a major part of a display device in accordance with Embodiment 5.

FIG. 13 is a diagram depicting, side by side, an energy band structure of each layer in a red-light-emitting element, an energy band structure of each layer in a green-light-emitting element, and an energy band structure of each layer in a blue-light-emitting element in accordance with Embodiment 5.

FIG. 14 is a schematic cross-sectional view of an example of a structure of a major part of a display device in accordance with a variation example of Embodiment 5.

FIG. 15 is a schematic cross-sectional view of an example of a structure of a major part of a display device in accordance with Embodiment 6.

### DESCRIPTION OF EMBODIMENTS

### Embodiment 1

The following will describe an embodiment of the present disclosure. Note that throughout the following description, the language, “from A to B,” where A and B are both numerical values means “greater than or equal to A and less than or equal to B” unless otherwise mentioned. In addition, throughout the following description, the language like “component A underlies/is below component B” indicates that component A is formed in an earlier process or step than component B, and the language like “component A overlies/is on or above component B” indicates that component A is formed in a later process or step than component B.

Additionally, throughout the following description, for convenience of description, those members which have the same function as previously described members will be denoted by the same reference numerals, and description thereof is not repeated. The second and subsequent embodiments will describe differences from the embodiment(s) described earlier. It will be appreciated that the embodiments may be modified in a similarly manner to the embodiment(s) described earlier unless explicitly mentioned otherwise.

In addition, the compositions given by chemical formulas in the present disclosure are preferably stoichiometric compositions. It should be understood however that the compositions could be given as non-stoichiometric compositions.

### Brief Description of Structure of Light-Emitting Element

A light-emitting element in accordance with the present embodiment includes: a first electrode and a second electrode; a light-emitting layer provided between the first electrode and the second electrode; and a charge transport layer provided between the first electrode and the light-emitting layer. The charge transport layer contains a metal oxide and includes a first area and a second area that exhibits a higher oxygen vacancy concentration than the first area.

One of the first electrode and the second electrode is an anode, and the other electrode is a cathode. In the present disclosure, the layers between the first electrode and the second electrode are referred to as functional layers. The functional layers include at least the light-emitting layer and the charge transport layer.

The light-emitting element may have a known structure where the anode is an underlying-layer electrode and the cathode is an overlying-layer electrode and may have an inverted structure where the cathode is an underlying-layer electrode and the anode is an overlying-layer electrode. In addition, the charge transport layer may be an electron transport layer and may be a hole transport layer. Throughout the following description, the “light-emitting layer” may be referred to as the “EML,” and the charge transport layer may be referred to as the “CTL.” Additionally, the electron transport layer may be referred to as the “ETL,” and the hole transport layer may be referred to as the “HTL.”

The light-emitting element may include either only the ETL or only the HTL as a CTL. In addition, the light-emitting element may include a CTL between the first electrode and the EML and another CTL between the second electrode and the EML. Therefore, the light-emitting element may include both the ETL and the HTL as CTLs. When the light-emitting element includes an ETL and an HTL as CTLs, either one or both of the ETL and the HTL need(s) only to contain a metal oxide and to include the first area and the second area.

The following description discusses an example where the light-emitting element has a known structure where the anode is an underlying-layer electrode and the cathode is an overlying-layer electrode and also where the ETL is a CTL containing a metal oxide and including the first area and the second area in a plan view (hereinafter, may be referred to as a “first CTL”). The following description discusses an example where the first area and the second area do not overlap each other. Alternatively, the first area and the second area may partially overlap each other.

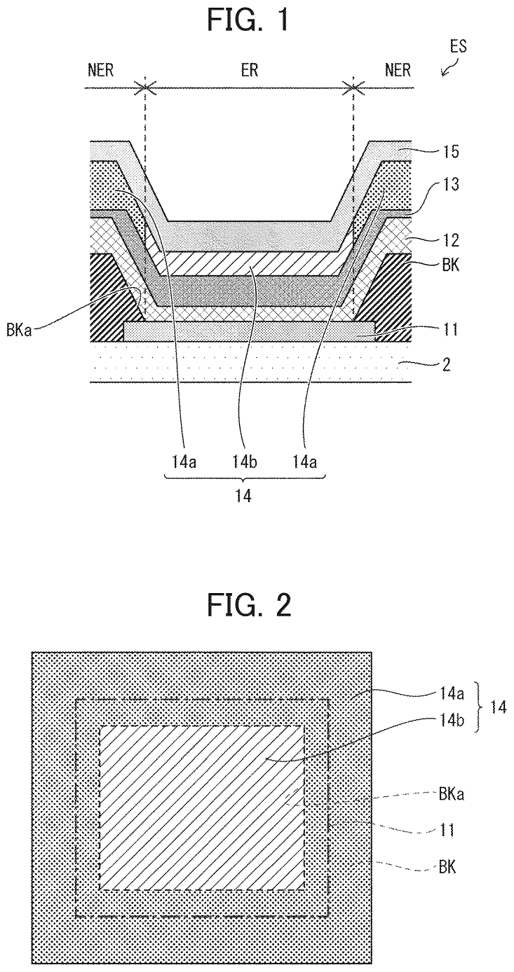

FIG. 1 is a schematic cross-sectional view of an example of a light-emitting element ES in accordance with the present embodiment. FIG. 2 is a plan view of an anode 11, a bank BK, and an ETL 14 in the light-emitting element ES shown in FIG. 1, as viewed from above the ETL 14.

Referring to FIG. 1, the light-emitting element ES in accordance with the present embodiment includes, for example: the anode 11 and a cathode 15; an EML 13 provided between the anode 11 and the cathode 15; and the ETL 14 provided between the cathode 15 and the EML 13. Note that the light-emitting element ES may, where necessary, include an HTL 12 between the anode 11 and the EML 13 as shown in FIG. 1.

Referring to FIG. 1, the anode 11 is formed as a pattern and is smaller than the cathode 15 in a plan view. The anode 11 has an edge covered with the insulating bank BK that does not transmit visible light.

The light-emitting element ES shown in FIG. 1 includes the anode 11, the bank BK, the HTL 12, the EML 13, the ETL 14, and the cathode 15, all of which are provided in this order when viewed from the underlying layer side (e.g., when viewed from the substrate 2).

All these layers from the anode 11 through the cathode 15 are typically provided on a substrate as a support body. Therefore, the light-emitting element ES may include, for example, the substrate 2 as a support body.

As described above, the substrate 2 is a support body for forming all the layers from the anode 11 through the cathode 15. The substrate 2 may be, for example, a rigid inorganic substrate such as a glass substrate and may be, for example, a flexible substrate made primarily of a resin such as a polyimide.

Note that the light-emitting element ES may be, for example, used as a light source for a light-emitting device such as a display device. When the light-emitting element ES is, for example, a part of a light-emitting device such as a display device, the substrate 2 is a substrate for a light-emitting device such as a display device. Therefore, the light-emitting element ES per se may include the substrate 2 as a support body. Alternatively, the light-emitting element ES per se may not include the substrate 2, but sit on the substrate 2 provided as a support body for a light-emitting device such as a display device. When the substrate 2 is a substrate for a light-emitting device such as a display device, the substrate 2 may be, for example, an array substrate on which there are provided a plurality of thin film transistors (TFTs).

The anode 11 is an electrode for supplying holes (h⁺; see FIG. 13 detailed below) to the EML 13 under an applied voltage. The cathode 15 is an electrode for supplying electrons (e⁻; see FIG. 13 detailed below) to the EML 13 under an applied voltage. The anode 11 and the cathode 15 each contain a conductive material and are configured to have a voltage applied across the anode 11 and the cathode 15 when connected to a power supply (e.g., DC power supply) (not shown).

At least one of the anode 11 and the cathode 15 is a transparent electrode. Note that any one of the anode 11 and the cathode 15 may be a “reflective electrode” that reflects light. The light-emitting element ES allows light to be extracted on the transparent electrode side.

For instance, when the light-emitting element ES is a top-emission light-emitting element which emits light on the overlying-layer electrode side, a transparent electrode is used as the overlying-layer electrode, and a reflective electrode is used as the underlying-layer electrode. Meanwhile, when the light-emitting element ES is a bottom-emission light-emitting element which emits light on the underlying-layer electrode side, a transparent electrode is used as the underlying-layer electrode, and a reflective electrode is used as the overlying-layer electrode.

The transparent electrode contains, for example, an electrically conductive light-transmitting material that transmits visible light such as ITO (indium tin oxide), IZO (indium zinc oxide), ZnO, AZO (aluminum-doped zinc oxide, alternatively termed as “ZAO”), BZO (boron-doped zinc oxide), or FTO (fluorine-doped tin oxide).

The reflective electrode suitably contains, for example, an electrically conductive light-reflective material that exhibits high reflectance to visible light including, for example, a metal such as Al, Cu, Au, or Ag or an alloy such as MgAg containing these metals. Note that the reflective electrode may be provided by stacking a layer composed of these light-transmitting materials and a layer composed of these light-reflective materials.

The bank BK functions as an edge cover for preventing, for example, concentration of electric field at the ends of the patterned underlying-layer electrode and short-circuiting of the underlying-layer electrode and the overlying-layer electrode. Referring to FIGS. 1 and 2, the bank BK is formed surrounding the underlying-layer electrode, so as to cover the ends of the patterned underlying-layer electrode (the anode 11 in the example shown in FIG. 1). In a plan view, the bank BK, covering the ends of this patterned underlying-layer electrode, has therein an opening BKa that provides a light-emitting region ER. Note that throughout the following description, the region overlapping the bank BK will be referred to as a region NER to distinguish this region from the light-emitting region ER.

The EML 13 is a layer that contains a light-emitting material and that emits light upon recombination of the holes transported from the anode 11 and the electrons transported from the cathode 15.

The light-emitting element ES may be, for example, a QLED (quantum-dot light-emitting diode) or an OLED (organic light-emitting diode).

When the light-emitting element ES is a QLED, the EML 13 contains a plurality of quantum dots (hereinafter, will be referred to as “QDs”) as a light-emitting material.

QDs are dots with a maximum width of 100 nm or smaller. In some typical cases, QDs are referred to as semiconductor nanoparticles because their composition is based on semiconductor materials. In addition, QDs may be referred to as nanocrystals because their structure has, for example, a unique crystal structure.

QDs may have any shape so long as the QDs have the aforementioned maximum width. QDs do not need to have any particular shape and are not limited to have a three-dimensional spherical shape (circular cross-sectional shape). The shape may be, for example, a polygonal cross-sectional shape, a virgulate three-dimensional shape, a ramal three-dimensional shape, a three-dimensional shape with an irregular surface, or a combination of any of these shapes.

The aforementioned QDs are not limited in any particular manner and may be any publicly known QDs. The QDs may have a core structure and may have a core-shell structure or a core-multishell structure both of which contains a core and a shell. When the QDs contain a shell, the core needs only to be positioned at the center, and the shell be disposed on the surface of the core. The shell preferably covers the whole core, but does not need to completely cover the core. In addition, the QDs may have a two-component core structure, a three-component core structure, or a four-component core structure. Note that the QDs may contain doped nanoparticles or may have a structure that exhibits a composition gradient.

The core may contain, for example, Si, Ge, CdSe, CdS, CdTe, InP, GaP, InN, ZnSe, ZnS, ZnTe, CdSeTe, GaInP, or ZnSeTe. The shell may contain, for example, CdS, ZnS, CdSeS, CdTeSe, CdSTe, ZnSeS, ZnSTe, ZnTeSe, or AlP.

The QDs can emit light at various emission wavelengths depending on, for example, the particle diameter and/or the composition of the particles. The aforementioned QDs emit visible light and allows controlling the emission wavelength from the blue wavelength range to the red wavelength range by suitably adjusting the particle diameter and the composition of the QDs.

Ligands may be coordinated to the surface of the QDs, and the EML 13 may contain QDs and ligands. The EML 13 may contain any ligands including, for example, any publicly known ligands. These ligands may be either organic or inorganic.

When the light-emitting element ES is an OLED, the EML 13 may contain, as a light-emitting material, an organic light-emitting material such as a low-molecular fluorescent (or phosphorescent) pigment or a metal complex.

The ETL 14 is an electron-transportable layer for transporting electrons from the cathode 15 to the EML 13. The ETL 14 is an oxide-based transport layer containing a metal oxide. The aforementioned metal oxide preferably contains, for example, at least one species selected from the group consisting of zinc oxide (ZnO), aluminum zinc oxide (AlZnO), lithium zinc oxide (LiZnO), and magnesium zinc oxide (MgZnO) and more preferably contains either one or both of zinc oxide and magnesium zinc oxide. Particularly, zinc oxide and magnesium zinc oxide are commonly used as a material for the ETL 14 and are readily available. In addition, these metal oxides readily enable reducing the elemental oxygen ratio and increasing the oxygen vacancy concentration by, for example, being irradiated with light such as ultraviolet light (UV light), which in turn enables increasing the electrical conductivity and achieving a high luminous efficiency.

Referring to FIGS. 1 and 2, in a plan view, the ETL 14 includes two regions that have different oxygen vacancy concentrations: namely, a first area 14a and a second area 14b that exhibits a higher oxygen vacancy concentration than does the first area 14a.

The first area 14a is a low oxygen vacancy concentration region, of the ETL 14, that has a relatively low oxygen vacancy concentration, and the second area 14b is a high oxygen vacancy concentration region, of the ETL 14, that has a relatively high oxygen vacancy concentration.

As described earlier, the light-emitting element ES includes the light-emitting region ER and the region NER. The light-emitting element ES has a low luminous efficiency in regions where there are provided no electrodes (in the present embodiment, regions where no anode 11 is provided) and in the region NER where the bank BK is provided. As described here, the electric current that flows in the regions where the luminous efficiency is low (excess current) can be a cause for reducing the luminous efficiency, such as the external quantum efficiency, of the light-emitting element ES.

Accordingly, the present embodiment relatively reduces the excess current flowing in the region NER where the luminous efficiency is low, by increasing the electric current flowing in the light-emitting region ER. This particular configuration hence increases the electric current that contributes to improvement of the luminous efficiency, relatively reduces the useless electric current that does not contribute to improvement of the luminous efficiency, and hence improves the overall luminous efficiency.

As described above, the ETL 14 is an oxide-based transport layer containing a metal oxide. Oxides such as metal oxides have oxygen vacancies (vacancies in an oxygen lattice). Oxygen vacancy concentration and electrical conductivity have a positive correlation, and oxygen vacancy concentration increases with an increase in electrical conductivity.

Therefore, in the ETL 14, the region that corresponds to the light-emitting region ER is preferably the second area 14b, and the region that corresponds to the region NER is preferably the first area 14a.

Hence, the electrical conductivity can be improved in the light-emitting region ER and hence relatively reduced in the region NER. Consequently, the electric current flowing in the light-emitting region ER can be increased, and the excess current flowing in the region NER where the luminous efficiency is low can be relatively reduced. In addition, hence, the overall luminous efficiency of the light-emitting element ES can be improved.

Note that the region, of the ETL 14, that corresponds to the light-emitting region ER preferably matches the second area 14b, and the region, of the ETL 14, that corresponds to the region NER preferably matches the first area 14a, as shown in FIGS. 1 and 2. However, it is difficult to completely match these regions.

Accordingly, the present embodiment assumes margins and designates a region, of the ETL 14, that corresponds to at least a part of the light-emitting region ER as the second area 14b and designates a region, of the ETL 14, that corresponds to at least a part of the region NER as the first area 14a.

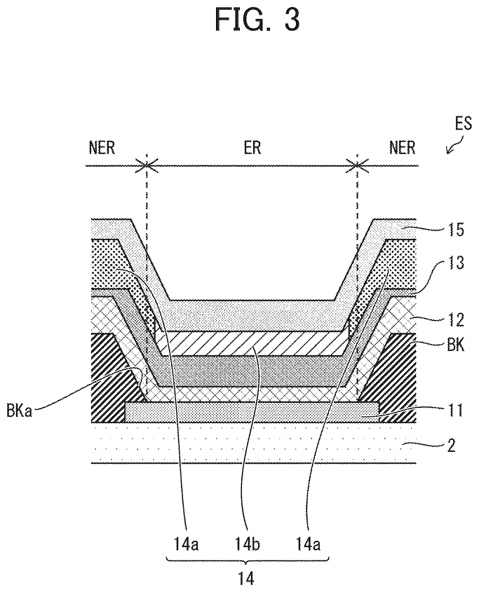

FIGS. 3 to 5 are a schematic cross-sectional view of an example of a relationship between the light-emitting region ER and the region NER and the first area 14a and the second area 14b in the light-emitting element ES in accordance with the present embodiment.

The region of the light-emitting element ES other than the light-emitting region ER is the region NER, and the region of the ETL 14 other than the first area 14a is the second area 14b.

Referring to FIG. 3, the light-emitting element ES may include the light-emitting region ER and the region NER, and the second area 14b may be provided in a region, of the ETL 14, that corresponds to at least a part of the light-emitting region ER. When this is the case, the region, of the ETL 14, that corresponds to at least a part of the light-emitting region ER is the second area 14b, and the other region is the first area 14a. Therefore, in the light-emitting element ES, for example, the second area 14b may be provided in a region, of the ETL 14, that corresponds to a part of the light-emitting region ER, and the first area 14a may be provided in a region, of the ETL 14, that corresponds to the remaining part of the light-emitting region ER and to the region NER, as shown in FIG. 3.

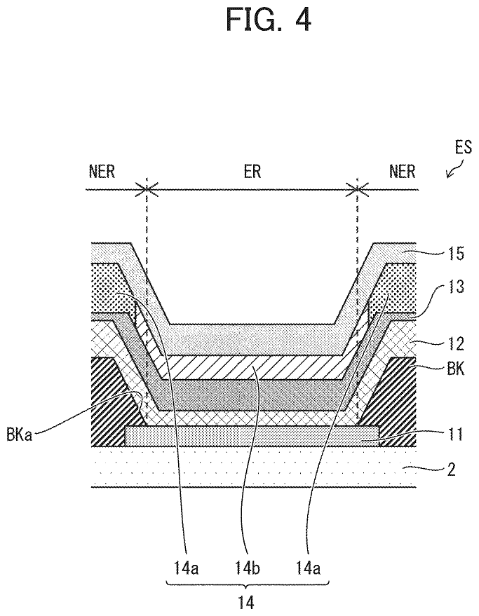

In addition, referring to FIG. 4, the light-emitting element ES may include the light-emitting region ER and the region NER, and the first area 14a may be provided in a region, of the ETL 14, that corresponds to at least a part of the region NER. When this is the case, the region, of the ETL 14, that corresponds to at least a part of the region NER is the first area 14a, and the other region is the second area 14b. Therefore, in the light-emitting element ES, for example, the first area 14a may be provided in a region, of the ETL 14, that corresponds to a part of the region NER, and the second area 14b may be provided in a region, of the ETL 14, that corresponds to the remaining part of the region NER and to the light-emitting region ER, as shown in FIG. 4.

It should be understood however that in the light-emitting element ES, either the entire region, of the ETL 14, that corresponds to the region NER may not be the first area 14a as shown in FIGS. 1 to 3 or the entire region, of the ETL 14, that corresponds to the light-emitting region ER may not be the second area 14b as shown in FIGS. 1, 2, and 4.

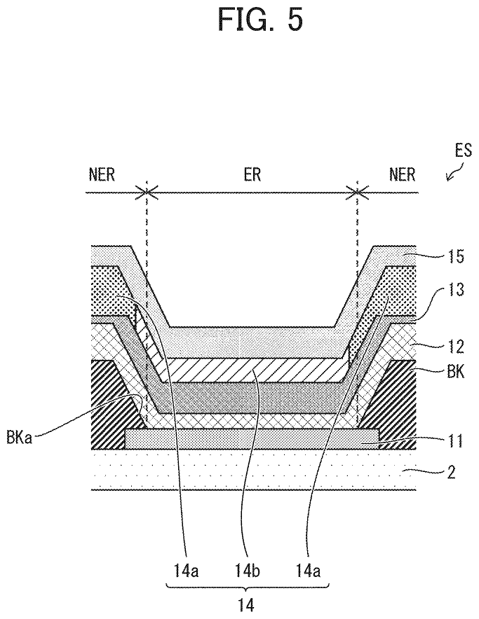

In the light-emitting element ES, if the area of the first area 14a is larger than the area of the second area 14b in the region, of the ETL 14, that corresponds to the region NER, and the area of the second area 14b is larger than the area of the first area 14a in the region, of the ETL 14, that corresponds to the light-emitting region ER, the second area 14b may be provided in the region, of the ETL 14, that corresponds to a part of the light-emitting region ER and in the region, of the ETL 14, that corresponds to a part of the region NER, and the first area 14a may be provided in the region, of the ETL 14, that corresponds to the remaining part of the light-emitting region ER and to the remaining part of the region NER, as shown in FIG. 5.

In any case, in the ETL 14, at least a part of the light-emitting region ER is a high oxygen vacancy concentration region and has a low elemental oxygen ratio and a relatively high electrical conductivity. Meanwhile, at least a part of the region NER is a low oxygen vacancy concentration region and has a high elemental oxygen ratio and a relatively low electrical conductivity.

Therefore, in any case, the excess current flowing in the region NER can be relatively reduced when compared with the electric current flowing in the light-emitting region ER. Therefore, the present embodiment enables relatively reducing excess current in comparison with when the ETL 14 includes no first area 14a and no second area 14b and also enables improving the luminous efficiency, such as the external quantum efficiency (EQE), of the light-emitting element ES.

Note that in the present embodiment, the first area 14a needs only to be provided so as to correspond to at least a part of the region NER as described above. However, the films formed in the vicinity of the bank BK are susceptible to defects, and it is difficult to form uniform films in the vicinity of the bank BK. In the vicinity of the bank BK, luminous efficiency is lower in the region where no uniform film is formed than in the region where a uniform film is formed. Throughout the following description, the region in the vicinity of the bank BK and inside the opening BKa in the bank BK where no uniform film is formed, which is a light-emitting region ER, may be referred to as a “defective film-formed region.” In addition, the region inside the opening BKa in the bank BK and other than the defective film-formed region may be referred to as a “normal film-formed region.” The defective film-formed region is a part of the light-emitting region ER, including the ends of the light-emitting region ER. The normal film-formed region is a region surrounded by the defective film-formed region, including the central portion of light-emitting region ER, but excluding the defective film-formed region.

Referring to FIG. 3, the excess current flowing in the region, inside the light-emitting region ER, where luminous efficiency is relatively low can be relatively reduced by providing the second area 14b in the region, of the ETL 14, that corresponds to a part of the light-emitting region ER excluding the defective film-formed region in the vicinity of the bank BK.

As described here, the luminous efficiency of the light-emitting element ES can be further improved by deliberately designating the region that, despite being a part of the light-emitting region ER, exhibits a relatively low luminous efficiency as the first area 14a. In addition, this structure allows for easy manufacturing and is desirable in view of margins.

The provision of the first area 14a and the second area 14b in the ETL 14 can be verified through a PL (photoluminescent) light emission spectrum. In addition, the oxygen vacancy concentration in the first area 14a and the second area 14b can be verified through a PL light-emission intensity. Note that depending on the oxygen vacancy concentration, the oxygen vacancy concentration may be determined by examining the elemental composition ratio of the ETL 14 by cross-sectional EDX (energy dispersive X-ray spectroscopy).

It should be understood however that to achieve the above-described effects, the oxygen vacancy concentration in the first area 14a needs only to be lower than the oxygen vacancy concentration in the second area 14b so that the excess current flowing in the first area 14a is relatively reduced when compared with the electric current flowing in the second area 14b. Therefore, in the present embodiment, the oxygen vacancy concentrations in the first area 14a and in the second area 14b are not limited in any particular manner.

The HTL 12 is a CTL containing a hole transport material to transport holes from the anode 11 to the EML 13. As described above, when the ETL 14 is an oxide-based transport layer including the first area 14a and the second area 14b, the HTL 12 may contain either an organic material or an inorganic material as a hole transport material.

This organic material may be, for example, poly[N,N′-bis(4-butylphenyl)-N,N′-bis(phenyl)-benzidine] (abbreviated as p-TPD) or poly[(9,9-dioctylfluorenyl-2,7-diyl)-co-(4,4′-(N-4-sec-butyl phenyl))diphenylamine)] (abbreviated as TFB).

The inorganic material may be a metal oxide, and the HTL 12 may be an oxide-based transport layer containing a metal oxide. When the HTL 12 is such an oxide-based transport layer, the metal oxide may be, for example, at least one species selected from the group consisting of nickel oxide (NiO), copper oxide (CuO), vanadium oxide (VOx), titanium oxide (TiOx), molybdenum oxide (MoOx), and tungsten oxide (WOx).

### Method for Manufacturing Light-Emitting Element ES

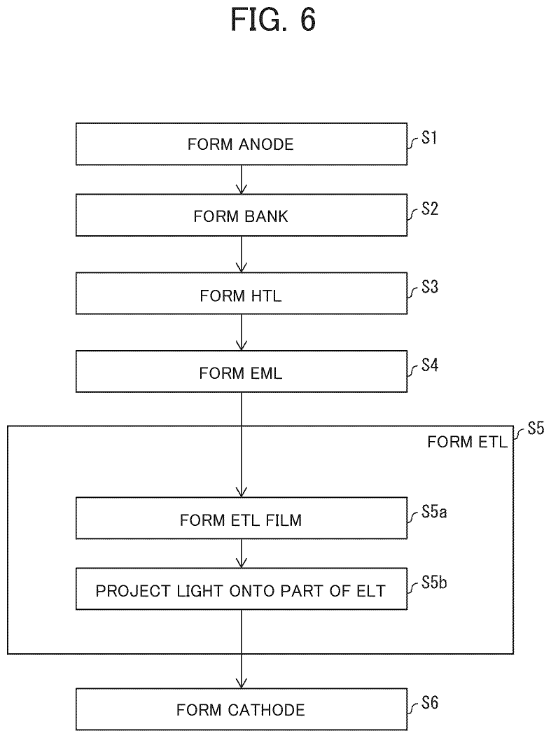

A description is now given of a method for manufacturing the light-emitting element ES in accordance with the present embodiment by taking a method for manufacturing the light-emitting element ES shown in FIG. 1 as an example. FIG. 6 is a flow chart representing an example of a method for manufacturing the light-emitting element ES shown in FIG. 1.

Referring to FIG. 6, in the aforementioned method for manufacturing the light-emitting element ES, first, the anode 11 is formed, for example, as the second electrode on the substrate 2 which is a support body (step S1, anode-formation step, second-electrode-formation step). Next, the bank BK is formed so as to cover the edge of the anode 11 (step S2, bank-formation step). Next, the HTL 12 is formed (step S3, hole-transport-layer-formation step). Next, the EML 13 is formed (step S4, light-emitting-layer-formation step). Next, the ETL 14 is formed as the first CTL (step S5, electron-transport-layer-formation step, charge-transport-layer-formation step). Step S5 includes an electron-transport-layer-film-formation step (step S5a, charge-transport-layer-film-formation step) and a light-exposure step (step S5b). In step S5, the ETL 14 including the first area 14a and the second area 14b is formed as the first CTL including a low oxygen vacancy concentration region and a high oxygen vacancy concentration region, by performing step S5a and step S5b. Next, the cathode 15 is formed (step S6, cathode-formation step). The light-emitting element ES is hence manufactured.

The method for manufacturing the light-emitting element ES in accordance with the present embodiment is the same as a known method for manufacturing a light-emitting element, except that step S5 includes step S5b.

The anode 11 is formed in step S1 and the cathode 15 is formed in step S6, both by, for example, vapor deposition or sputtering.

In step S2, the bank BK can be formed with a desirable shape by, for example, applying an organic material such as a polyimide or an acrylic resin and thereafter performing photolithographic patterning.

The EML 13 is formed in step S4 by, for example, spin-coating, inkjet printing, or vacuum vapor deposition.

The HTL 12 is formed in step S3, and the ETL 14 is formed in step S5a, both by, for example, spin-coating, inkjet printing, sputtering, vacuum vapor deposition, or sol-gel.

In the present embodiment, as described above, after step S5a, the light-exposure step (step S5b) is additionally performed in which parts of the ETL 14 formed in step S5a are selectively exposed to light.

The ETL 14 is exposed to light in step S5b, preferably, by mask exposure using a mask to restrict the light-irradiated area.

This selective exposure to light of parts of the ETL 14 increases oxygen vacancies in the exposed area irradiated with the light. Therefore, a region, of the ETL 14, that exhibits a higher oxygen vacancy concentration than a non-exposed area that is not exposed to light is formed in a part of the ETL 14 in a plan view, by selectively exposing parts of the ETL 14 to light. Hence, in the ETL 14, the non-exposed area is rendered the first area 14a, and the exposed area is rendered the second area 14b.

To manufacture the light-emitting element ES shown in FIG. 1, the region, of the ETL 14, that corresponds to the light-emitting region ER is exposed to light in aforementioned step S5b, so as to provide the first area 14a in a region, of the ETL 14, that corresponds to the region NER, and as to provide the second area 14b in a region, of the ETL 14, that corresponds to the light-emitting region ER. To this end, light is projected onto the region, of the ETL 14, that does not overlap the bank BK in a plan view (in other words, the region residing inside the opening BKa in the bank BK).

It should be understood however that in aforementioned step S5b, as described earlier, the region, of the ETL 14, that corresponds to at least a part of the light-emitting region ER may be exposed to light so as to provide the second area 14b in a region, of the ETL 14, that corresponds to at least a part of the light-emitting region ER. Alternatively, in aforementioned step S5b, as described earlier, the region, of the ETL 14, that corresponds to at least a part of the region NER may be exposed to light so as to provide the first area 14a in a region, of the ETL 14, that corresponds to at least a part of the region NER.

In any case, the light-emitting element ES, which includes the first area 14a and the second area 14b which has a difference in electrical conductivity and which boasts a high luminous efficiency, can be readily manufactured by the aforementioned method.

The aforementioned light may be, for example, UV light as described earlier. It should be understood however that the light is not necessarily UV light and is not limited in any particular manner so long as oxygen vacancies can be produced.

In addition, the irradiation intensity of the light is not limited in any particular manner and needs only to be sufficiently high to produce oxygen vacancies.

Similarly, the irradiation time of the light is not limited in any particular manner and needs only to be specified in such a suitable manner as to obtain an oxygen vacancy concentration that can achieve desirable electrical conductivity.

As described earlier, oxygen vacancy concentration and electrical conductivity have a positive correlation. Therefore, as described above, the region that has such a low luminous efficiency that the electric current flowing therein should be as small as possible is rendered the first area 14a, by adjusting the oxygen vacancy concentration of the metal oxide to provide the first area 14a and the second area 14b in the ETL 14. Then, the region other than the first area 14a, for example, as described earlier, the region that has such a high luminous efficiency contributing to improvement of luminous efficiency that the electric current flowing therein should be actively increased is rendered the second area 14b. Then, as described above, a difference in the oxygen vacancy concentration is introduced between the first area 14a and the second area 14b to increase the electric current flowing in the second area 14b and hence relatively reduce the excess current flowing in the first area 14a. This configuration, as described above, can provide the light-emitting element ES in which the excess current is relatively reduced and the luminous efficiency such as the EQE is high and can also provide a method for manufacturing the light-emitting element ES.

Note that as described above, the present embodiment has so far discussed an example where the light-emitting element ES is a light-emitting element that has a known structure in which the anode 11 is an underlying-layer electrode and the cathode 15 is an overlying-layer electrode. However, the present embodiment is by no means limited to this example. Alternatively, the light-emitting element ES may have an inverted structure in which the cathode 15 is an underlying-layer electrode and the anode 11 is an overlying-layer electrode, as discussed in an embodiment detailed later.

In addition, as described above, the present embodiment has so far discussed an example where the ETL 14 is the first CTL that contains a metal oxide and that includes the first area 14a, which is a low oxygen vacancy concentration region, and the second area 14b, which is a high oxygen vacancy concentration region. However, the present embodiment is by no means limited to this example. Alternatively, as discussed in an embodiment detailed later, in the light-emitting element ES, the HTL 12 may be the first CTL that contains a metal oxide and that includes the first area, which is a low oxygen vacancy concentration region, and the second area, which is a high oxygen vacancy concentration region.

### Embodiment 2

As described earlier, the light-emitting element ES may be, for example, used as a light source for a light-emitting device such as a display device. The following description discusses the aforementioned light-emitting device by taking a display device including the light-emitting element ES shown in FIG. 1 as an example.

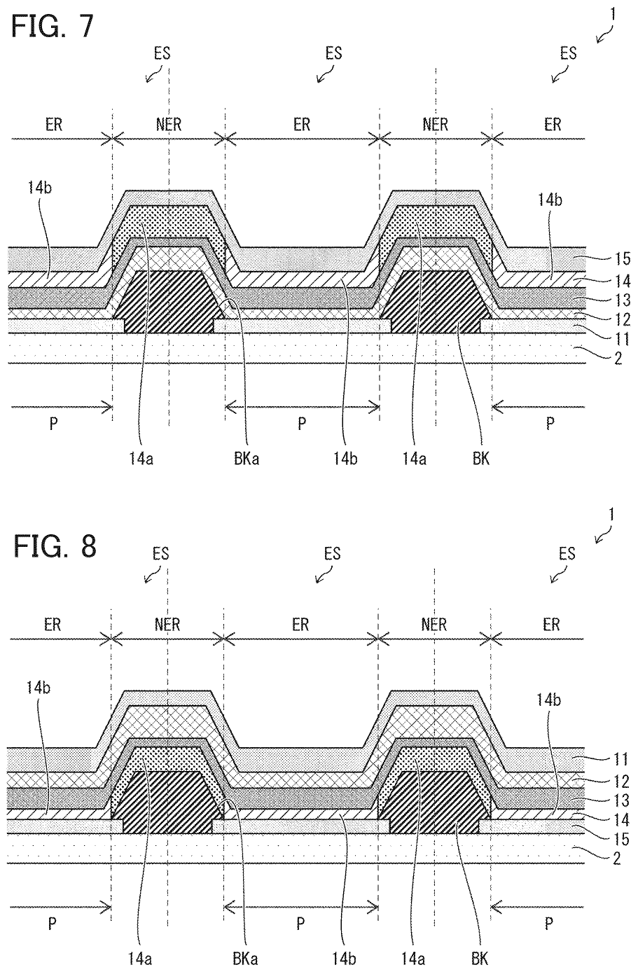

FIG. 7 is a schematic cross-sectional view of an example of a structure of a major part of a display device 1 (light-emitting device) in accordance with the present embodiment.

The display device 1 has a plurality of pixels P. Each pixel P includes the light-emitting element ES. The bank BK is provided between the pixels P, so that the light-emitting regions ER of the light-emitting elements ES are separated by the bank BK. Therefore, the bank BK functions as an edge cover as described earlier and also functions both as a pixel partition wall for partitioning the pixels P and as a partition wall for separating the light-emitting regions ER of the light-emitting elements ES.

The display device 1 includes, as the substrate 2, for example, an array substrate where a plurality of TFTs are formed and also has a structure in which a light-emitting element layer 3 including the plurality of light-emitting elements ES is stacked on the substrate 2.

FIG. 7 shows an example where the display device 1 is a display device that emits monochromatic light as an example. The light-emitting element ES may be a white light-emitting element that emits white light and may be a red-light-emitting element that emits red light, a green-light-emitting element that emits green light, or a blue-light-emitting element that emits blue light.

The light-emitting element layer 3 contains the plurality of light-emitting elements ES provided respectively for the pixels P. Therefore, the display device 1 has a structure in which each layer of these light-emitting elements ES is stacked as the light-emitting element layer 3 on the substrate 2.

In such a case, as described above, the substrate 2 is an array substrate. The array substrate is provided with, for example, a TFT layer including the plurality of TFTs formed therein. The TFT layer includes a pixel circuit including drive elements such as the TFTs for controlling the light-emitting elements ES.

The light-emitting element layer 3 includes a plurality of anodes 11, the bank BK covering the edge of each anode 11, the HTL 12, the EML 13, the ETL 14, and the cathode 15, constituting the light-emitting elements ES, all of which are stacked in this order when viewed from the substrate 2.

The anodes 11 function as pixel electrodes (insular underlying-layer electrodes) provided respectively for the plurality of pixels P and are provided respectively for the pixels P (in other words, respectively for the light-emitting elements ES) in an insular manner on the substrate 2.

The cathode 15 is provided as a common electrode (common upper electrode) provided commonly to all the pixels P, in other words, commonly to the plurality of pixels P and is provided commonly to all the light-emitting elements ES. The light-emitting elements ES function as a light source for illuminating the pixels P.

The display device 1 may be a monochromatic display device for displaying fixed figures such as a traffic signal, and the EML 13 may be provided commonly to the plurality of pixels as shown in FIG. 7. Alternatively, a plurality of EMLs 13 may be formed respectively for the pixels P in an insular manner as described in an embodiment detailed later.

In addition, a plurality of HTLs 12 and a plurality of ETLs 14 may also be formed respectively for the pixels Pin an insular manner. Alternatively, one HTL 12 and one ETL 14 may be provided as a common layer for the plurality of pixels P as shown in FIG. 7. This formation of the single HTL 12 or the single ETL 14 as a common layer across the plurality of light-emitting elements ES enables simple and convenient formation of these CTLs in each pixel P.

### Method for Manufacturing Display Device 1

A description is given next of a method for manufacturing the display device 1 shown in FIG. 7.

A method for manufacturing the display device 1 includes a light-emitting-element-layer-formation step of forming, on the array substrate as the substrate 2, the light-emitting element layer 3 including the plurality of light-emitting elements ES provided respectively for the pixels P. The light-emitting elements ES in the display device 1 may be manufactured by a manufacturing method similarly to the light-emitting element ES in accordance with Embodiment 1. Therefore, the light-emitting-element-formation step may be a light-emitting-element-manufacturing step for manufacturing the plurality of light-emitting elements ES by the method for manufacturing the light-emitting element ES described in Embodiment 1.

In the light-emitting-element-layer-formation step, referring to FIG. 7, in aforementioned step S1, the anodes 11 are formed respectively for the pixels P as, for example, the second electrodes on the array substrate as the substrate 2. Next, in step S2, the bank BK is formed so as to cover the edges of each anodes 11. Next, in step S3, the HTL 12 is formed across, and commonly to, all the plurality of pixels P. Next, in step S4, the EML 13 is formed. The EML 13 may be formed across, and commonly to, all the plurality of pixels P, or a plurality of EMLs 13 may be formed respectively for the pixels P in an insular manner, depending on the use thereof, as shown in FIG. 7.

Next, in step S5, the ETL 14 is formed as the first CTL. In step S5, after the ETL 14 is formed as a film (as a single piece) across, and commonly to, all the plurality of pixels P as step S5a, the ETL 14 formed in step S5a is partially exposed to light in step S5b. In so doing, in step S5b, the region, of the ETL 14, that corresponds to the opening BKa in the bank BK, in other words, the region, of the ETL 14, that does not overlap the bank BK in a plan view, is exposed to light. Hence, the region, of the ETL 14, that corresponds to the light-emitting region ER of each pixel P is rendered the second area 14b, and the region, of the ETL 14, that overlaps the bank BK and that corresponds to the region NER between the pixels P is rendered the first area 14a.

When the region, of the ETL 14, that corresponds to the region NER between the pixels P is rendered the first area 14a, and the region, of the ETL 14, that corresponds to the light-emitting region ER of each pixel P is rendered the second area 14b, the second area 14b ideally has the same shape as the pixel P in a plan view. The second areas 14b are arranged, for example, in a matrix. The first area 14a is formed like a lattice surrounding each second area 14b so as to partition the adjacent second areas 14b. As described here, the ETL 14 can be formed for each pixel P in a simple and convenient manner in step S5, by forming the ETLs 14 as a single piece across the plurality of pixels P, in other words, across the plurality of light-emitting elements ES. Next, in step S6, the cathode 15 is formed across, and commonly to, all the pixels P. The light-emitting element layer 3 is hence formed that includes the plurality of light-emitting elements ES provided respectively for the pixels P on an array substrate as the substrate 2.

Note that the display device 1 may have a structure in which a sealing layer (not shown) is formed on the light-emitting element layer 3 and may further include a sealing-layer-formation step of forming a sealing layer covering the light-emitting element layer 3 after the light-emitting-element-layer-formation step.

In addition, the method for manufacturing the display device 1 may further include a substrate-formation step of forming an array substrate as the substrate 2 before the light-emitting-element-layer-formation step. The substrate-formation step may include a TFT-layer-formation step of forming the aforementioned TFT layer. Note that these steps are performed by an apparatus for manufacturing the display device 1.

In addition, FIG. 7 shows an example where the HTL 12 is a common layer common to the plurality of pixels P and is formed across, and commonly to, all the plurality of pixels P in step S3. Alternatively, the HTL 12 may be formed in an insular manner for each pixel P. As described above, optical crosstalk where adjacent light-emitting elements ES (pixels P) are also turned on can be restrained, by forming the HTL 12 in each pixel P in an insular manner when the display device 1 including the light-emitting element ES and the light-emitting element ES has a known structure.

In addition, also in the present embodiment, in aforementioned step S5b, the region, of the ETL 14, that corresponds to at least a part of each light-emitting region ER of each pixel P may be exposed to light, so as to provide the second area 14b in the region, of the ETL 14, that corresponds to at least a part of the light-emitting element ES. Alternatively, in aforementioned step S5b, the region, of the ETL 14, that corresponds to at least a part of each region NER may be exposed to light, so as to provide the first area 14a in the region, of the ETL 14, that corresponds to at least a part of each region NER between the pixels P.

In any case, the display device 1 in accordance with the present embodiment can increase the electric current flowing in the second area 14b and hence relatively reduce the excess current flowing in the first area 14a, by the inclusion of the light-emitting element ES in accordance with Embodiment 1. The display device 1 can be hence provided with a relatively reduced excess current and a high luminous efficiency, for example, a high EQE. In addition, the method for manufacturing the display device 1 in accordance with the present embodiment includes, as a light-emitting-element-layer-manufacturing step, a light-emitting-element-manufacturing step of manufacturing the plurality of light-emitting elements ES by the method for manufacturing the light-emitting element ES described in Embodiment 1. The method for manufacturing the display device 1 can be hence provided which enables the manufacture of the display device 1 with a high luminous efficiency, for example, with a high EQE.

### Embodiment 3

As described earlier, the light-emitting element ES may have an inverted structure in which the cathode 15 is an underlying-layer electrode and the anode 11 is an overlying-layer electrode. The following description discusses an example where the display device 1 is a display device with an inverted structure including the light-emitting elements ES with an inverted structure.

FIG. 8 is a schematic cross-sectional view of an example of a structure of a major part of the display device 1 in accordance with the present embodiment.

The display device 1 shown in FIG. 8 has the same structure as the display device 1 in accordance with Embodiment 2, except for the following points.

The display device 1 shown in FIG. 8 has a structure in which each light-emitting element ES in the light-emitting element layer 3 includes the cathodes 15, the bank BK, the ETL 14, the EML 13, the HTL 12, and the anode 11, all of which are stacked in this order when viewed from the array substrate as the substrate 2.

In the present embodiment, the cathodes 15 function as pixel electrodes (insular underlying-layer electrodes) provided respectively for the plurality of pixels P and are provided in an insular manner on the substrate 2 for the respective pixels P (in other words, for the respective light-emitting elements ES).

The anode 11 is provided as a common electrode (common overlying-layer electrode) provided commonly to all the pixels P, in other words, commonly to the plurality of pixels P and is provided commonly to all the light-emitting elements ES.

As described here, the first electrode may be a pixel electrode provided for each of the plurality of pixels P, the second electrode may be a common electrode provided commonly to the plurality of pixels P, and the ETL 14, which is the first CTL, in the plurality of light-emitting elements ES may be provided closer to the pixel electrode than the EML 13 is close to the pixel electrode.

### Method for Manufacturing Display Device 1

A description is given next of a method for manufacturing the display device 1 shown in FIG. 8.

As described in Embodiment 2, the light-emitting element layer 3 has a structure in which the light-emitting element ES includes stacked layers. Therefore, in the light-emitting-element-layer-formation step (light-emitting-element-manufacturing step) in the method for manufacturing the display device 1 in accordance with the present embodiment, the layers in the light-emitting element ES, excluding the bank BK, are stacked in a reverse order when compared to Embodiment 2.

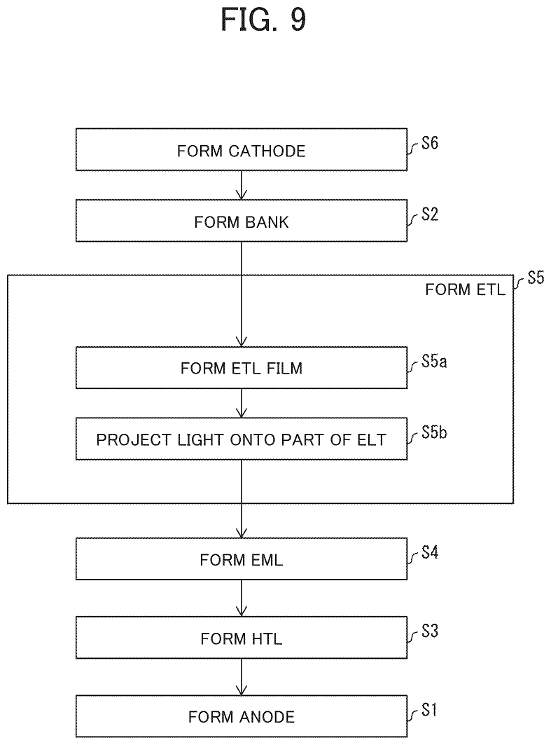

FIG. 9 is a flow chart representing an example of a method for manufacturing the light-emitting elements ES in the display device 1 shown in FIG. 8. The following description will discuss a method for manufacturing the light-emitting elements ES in the light-emitting-element-layer-formation step.

In the light-emitting-element-layer-formation step in accordance with the present embodiment, first, the cathodes 15 are formed as the first electrodes for the respective pixels P on an array substrate as the substrate 2, as shown in FIG. 9 (step S6, cathode-formation step, first-electrode-formation step). Next, the bank BK is formed so as to cover the edge of each cathode 15 (step S2, bank-formation step). Next, the ETL 14 is formed as the first CTL (step S5, electron-transport-layer-formation step). In step S5, first, the ETL 14 is formed as a film (as a single piece) across, and commonly to, all the plurality of pixels P (step S5a, charge-transport-layer-film-formation step, electron-transport-layer-film-formation step). Next, the ETL 14 formed in step S5a is partially exposed to light similarly to Embodiment 2 (step S5b, light-exposure step). The ETL 14 is hence formed which includes the first area 14a, which is a low oxygen vacancy concentration region, and the second area 14b, which is a high oxygen vacancy concentration region. Next, the EML 13 is formed similarly to Embodiment 2 (step S4, light-emitting-layer-formation step). Next, the HTL 12 is formed across, and commonly to, all the plurality of pixels P (step S3, hole-transport-layer-formation step). Next, the anode 11 is formed across, and commonly to, all the pixels P. The light-emitting element layer 3 is hence formed which includes the plurality of light-emitting elements ES provided respectively for the pixels P on an array substrate as the substrate 2.

The method for manufacturing the display device 1 in accordance with the present embodiment is the same as the method for manufacturing the display device 1 in accordance with Embodiment 2, except for the above-described points.

As described in the foregoing, also in the present embodiment, the display device 1 includes the light-emitting elements ES that include, as the first CTL, the ETL 14 containing a metal oxide and including the first area 14a and the second area 14b which exhibits a higher oxygen vacancy concentration than the first area 14a. Therefore, the present embodiment can similarly increase the electric current flowing in the second area 14b and hence relatively reduce the excess current flowing in the first area 14a. Therefore, the present embodiment can provide the light-emitting element ES and the display device 1 in which excess current is relatively reduced and luminous efficiency such as the EQE is high and can also provide a method for manufacturing the light-emitting element ES and a method for manufacturing the display device 1 that enable the manufacture of the light-emitting element ES and the display device 1.

In addition, as described above, the light-emitting-element-layer-formation step (light-emitting-element-manufacturing step) includes the first-electrode-formation step (step S6) of forming the first electrode before the charge-transport-layer-formation step in step S5. In addition, the light-emitting-layer-formation step of forming the EML 13 which is a light-emitting layer is included after the light-exposure step (step S5b). As described earlier, the light-emitting element ES and the display device 1 can be hence manufactured in both of which the ETLs 14 in the plurality of light-emitting elements ES are provided closer to the pixel electrode than the EML 13 is close to the pixel electrode. As described here, when the ETL 14 is exposed to light in a light-emitting element with an inverted structure (inverted element), the ETL 14 may be exposed to light before the EML 13 is formed.

The overlying-layer electrode is formed as the above-described common electrode across, and commonly to, all the plurality of pixels P so that the entirety thereof can be placed at the same electrical potential throughout the entirety. Meanwhile, the underlying-layer electrode is formed as a pixel electrode divided for each pixel P. Therefore, optical crosstalk can be sufficiently restrained owing to the inclusion of the first area 14a and the second area 14b in the ETL 14 which is provided closer to the pixel electrode than the EML 13 is close to the pixel electrode, even if the ETLs 14 in the plurality of light-emitting elements ES are formed as a single piece as described above.

### Embodiment 4

As described earlier, the first CTL may be an HTL. The following description discusses an example where the HTL is the first CTL containing a metal oxide and including the first area, which is a low oxygen vacancy concentration region, and the second area, which is high oxygen vacancy concentration region, in a plan view. The following description discusses an example where the first area and the second area do not overlap each other. Alternatively, as described earlier, the first area and the second area may partially overlap.

In addition, the following description discusses an example where the display device 1 is a display device with a known structure including light-emitting elements ES with a known structure. However, the present embodiment is by no means limited to this example. Alternatively, the light-emitting element ES and the display device 1 may have an inverted structure.

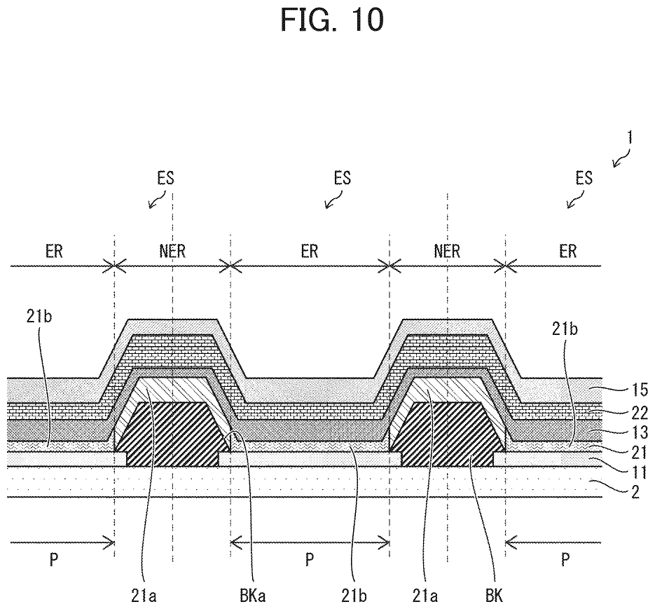

FIG. 10 is a schematic cross-sectional view of an example of a structure of a major part of the display device 1 in accordance with the present embodiment.

The display device 1 shown in FIG. 10 has the same structure as the display device 1 in accordance with Embodiment 2, except for the following points.

In the display device 1 shown in FIG. 10, each light-emitting element ES in the light-emitting element layer 3 includes the anode 11, the bank BK, an HTL 21, the EML 13, an ETL 22, and the cathode 15, all of which are stacked in this order when viewed from the array substrate as the substrate 2.

The HTL 21 is a CTL containing a hole transport material to transport holes from the anode 11 to the EML 13. The HTL 21 is the same as the HTL 12 in the light-emitting elements ES in accordance with Embodiments 1 to 3, except that the HTL 21 contains a metal oxide and includes a first area 21a and a second area 21b that exhibits a higher oxygen vacancy concentration than the first area 21a in a plan view. The metal oxide preferably includes, for example, at least one species selected from the group consisting of nickel oxide (NiO), copper oxide (CuO), vanadium oxide (VOx), titanium oxide (TiOx), molybdenum oxide (MoOx), and tungsten oxide (WOx). These metal oxides readily enable reducing the elemental oxygen ratio and increasing the oxygen vacancy concentration by, for example, being irradiated with light such as UV light, which in turn enables increasing the electrical conductivity and achieving a high luminous efficiency.

The first area 21a is a low oxygen vacancy concentration region that has a relatively low oxygen vacancy concentration in the HTL 21, and the second area 21b is a high oxygen vacancy concentration region that has a relatively high oxygen vacancy concentration in the HTL 21.

The ETL 22 is an electron-transportable layer for transporting electrons from the cathode 15 to the EML 13. When the HTL 21 is an oxide-based transport layer including the first area 21a and the second area 21b as described above, the ETL 22 is may be optionally provided as appropriate. The ETL 22 may include either an organic material or an inorganic material as an electron transport material.

This organic material may be, for example, 1,3,5-tris(1-phenyl-1H-benzimidazol-2-yl)benzene (TPBi), 3-(biphenyl-4-yl)-5-(4-tert-butylphenyl)-4-phenyl-4H-1,2,4-triazole (TAZ), bathophenanthroline (Bphen), or tris(2,4,6-trimethyl-3--(pyridin-3-yl)phenyl)borane (3 TPYMB).

The aforementioned inorganic material may be a metal oxide, and the ETL 22 may be an oxide-based transport layer containing a metal oxide. When the ETL 22 is such an oxide-based transport layer, the metal oxide may be, for example, a metal oxide similar to the metal oxide used in the ETL 14.

### Method for Manufacturing Display Device 1

A description is given next of a method for manufacturing the display device 1 shown in FIG. 10.

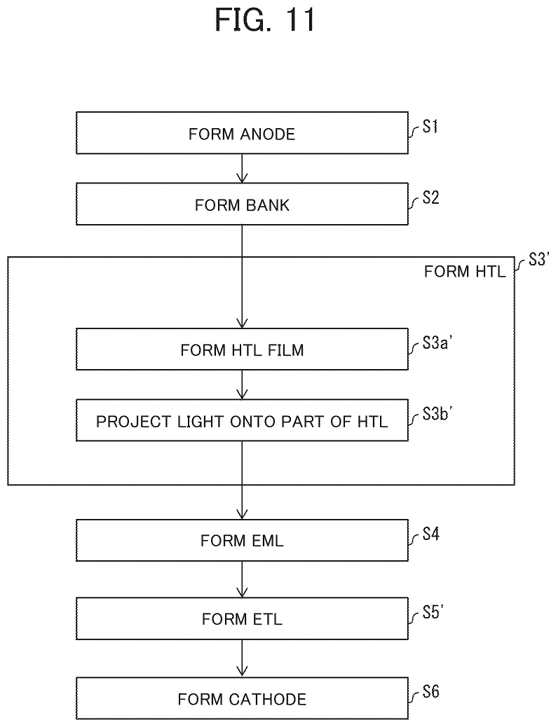

FIG. 11 is a flow chart representing an example of a method for manufacturing the light-emitting elements ES in the display device 1 shown in FIG. 10. The following description discusses a method for manufacturing the light-emitting elements ES in a light-emitting-element-layer-formation step.

Referring to FIG. 11, in the method for manufacturing the display device 1 in accordance with the present embodiment, first, similarly to Embodiment 2, step S1 and step S2 are performed, and thereafter, the HTL 21 is formed as the first CTL (step S3′, hole-transport-layer-formation step, charge-transport-layer-formation step).

Step S3′ includes a hole-transport-layer-film-formation step (step S3a′, charge-transport-layer-film-formation step) and a light-exposure step (step S3b′). In step S3′, after the HTL 21 is formed (as a single piece) across, and commonly to, all the plurality of pixels P as step S3a′, the ETL 14 formed in step S3a′ is partially exposed selectively to light in step S3b′. In so doing, in step S3b′, the region, of the HTL 21, that corresponds to the opening BKa in the bank BK, in other words, the region, of the HTL 21, that does not overlap the bank BK in a plan view, is exposed to light. Hence, the region, of the HTL 21, that corresponds to the light-emitting region ER of each pixel P is rendered the second area 21b, and the region, of the HTL 21, that overlaps the bank BK and that corresponds to the region NER between the pixels P is rendered the first area 21a.

Next, step S4 performed similarly to Embodiment 2 to form the EML 13 similarly to Embodiment 2. Next, the ETL 22 is formed across, and commonly to, all the plurality of pixels P (step S5′, electron-transport-layer-formation step). Step S5′ is the same as step S5 in Embodiment 2, except that step S5b is not performed. In other words, step S5′ is the same as step S5a in Embodiment 2. Next, the cathode 15 is formed across, and commonly to all the pixels P. The light-emitting element layer 3 is hence formed which includes the plurality of light-emitting elements ES provided respectively for the pixels P on an array substrate as the substrate 2.

The method for manufacturing the display device 1 in accordance with the present embodiment is the same as the method for manufacturing the display device 1 in accordance with Embodiment 2, except for the above-described points.

As described in the foregoing, in the present embodiment, the HTL 21 including the first area 21a and the second area 21b is formed as the first CTL including low oxygen vacancy concentration region and high oxygen vacancy concentration region, by performing step S3a′ and step S3b′ in step S3′.

Note that a mask may be used similarly in step S3b′ to restrict the light-irradiated area when the HTL 21 is exposed to light. When the first CTL is the HTL 21, the oxygen vacancies similarly increase in the irradiated area if the oxide-based transport layer containing a metal oxide is partially exposed selectively to light.

In the present embodiment, as described above, the region, of the HTL 21, that corresponds to the light-emitting region ER is exposed to light in aforementioned step S3b′, so as to provide the first area 21a in a region, of the HTL 21, that corresponds to the region NER and to provide the second area 21b in a region, of the HTL 21, that corresponds to the light-emitting region ER. To this end, light is projected onto the region, of the HTL 21, that does not overlap the bank BK in a plan view (in other words, the region residing inside the opening BKa in the bank BK).

It should be understood however that in aforementioned step S3b′, similarly to the aforementioned ETL 14, a region, of the HTL 21, that corresponds to at least a part of the light-emitting region ER may be exposed to light so as to provide the second area 21b in a region, of the HTL 21, that corresponds to at least a part of the light-emitting region ER. Alternatively, in aforementioned step S3b′, a region, of the HTL 21, that corresponds to at least a part of the region NER may be exposed to light so as to provide the first area 21a in a region, of the HTL 21, that corresponds to at least a part of the region NER.

In any case, the light-emitting element ES, which includes the first area 21a and the second area 21b that have a difference in electrical conductivity and which boasts a high luminous efficiency, can be readily manufactured by the aforementioned method.

Note that when the first CTL is the HTL 21, the aforementioned light is similarly, for example, UV light as described above. However, the light is not necessarily UV light so long as the light can produce oxygen vacancies.

In addition, the irradiation intensity of the light is not limited in any particular manner and needs only to be sufficiently high to produce oxygen vacancies.

Similarly, the irradiation time of the light is not limited in any particular manner and needs only to be specified in such a suitable manner as to obtain an oxygen vacancy concentration that can achieve desirable electrical conductivity.

As described in the foregoing, the display device 1 in accordance with the present embodiment includes the light-emitting elements ES that include, as the first CTL, the HTL 21 containing a metal oxide and including the first area 21a and the second area 21b that exhibits a higher oxygen vacancy concentration than the first area 21a. Therefore, the present embodiment can increase the electric current flowing in the second area 21b and hence relatively reduce the excess current flowing in the first area 21a. Therefore, the present embodiment can provide the light-emitting element ES and the display device 1 in which excess current is relatively reduced and luminous efficiency such as the EQE is high and can also provide a method for manufacturing the light-emitting element ES and a method for manufacturing the display device 1 that enable the manufacture of the light-emitting element ES and the display device 1.

In addition, as described above, the light-emitting-element-layer-formation step (light-emitting-element-manufacturing step) includes the first-electrode-formation step (step S1) of forming the first electrode before the charge-transport-layer-formation step in step S3′. In addition, the light-emitting-layer-formation step of forming the EML 13 which is a light-emitting layer is included after the light-exposure step (step S3b′). As described earlier, the light-emitting element ES and the display device 1 can be hence manufactured in both of which the HTLs 21 in the plurality of light-emitting elements ES are provided closer to the pixel electrode than the EML 13 is close to the pixel electrode. As described here, when the HTL 21 is exposed to light in a light-emitting element with a known structure (known element), the HTL 21 may similarly be exposed to light before the EML 13 is formed. As described here, optical crosstalk can be sufficiently restrained owing to the inclusion of the first area 21a and the second area 21b in the HTL 21, which is provided closer to the pixel electrode than the EML 13 is close to the pixel electrode, even if the HTLs 21 in the plurality of light-emitting elements ES are formed as a single piece as described above.

### Embodiment 5

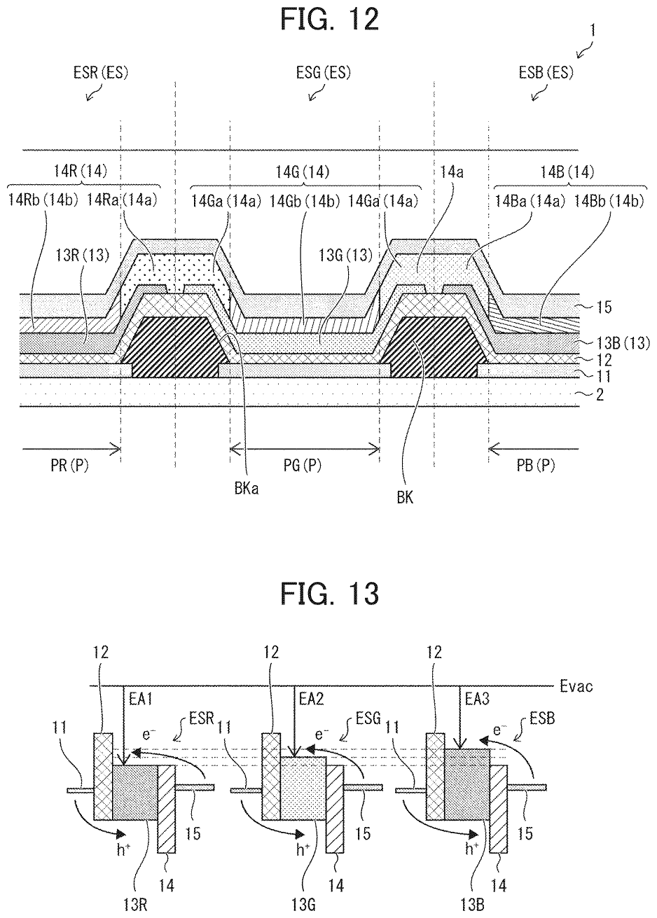

FIG. 12 is a schematic cross-sectional view of an example of a structure of a major part of the display device 1 in accordance with the present embodiment.

The display device 1 shown in FIG. 12 has the same structure as, for example, the display device 1 in accordance with Embodiment 2, except for the following points.

The display device 1 in accordance with the present embodiment includes a plurality of light-emitting elements ES that emit light of mutually different colors.

The display device 1 in accordance with the present embodiment is a full-color display device and includes pixels PR that are red pixels that emit red light, pixels PG that are green pixels that emit green light, and pixels PB that are blue pixels that emit blue light as the pixels P as shown in FIG. 12. In addition, the display device 1 includes light-emitting elements ESR that are red-light-emitting elements that emit red light, light-emitting elements ESG that are green-light-emitting elements that emit green light, and light-emitting elements ESB that are blue-light-emitting elements that emit blue light as the plurality of light-emitting elements ES that emit light of different colors. Each pixel PR includes one of the light-emitting elements ESR as the light-emitting element ES. Each pixel PG includes one of the light-emitting elements ESG as the light-emitting element ES. Each pixel PB includes one of the light-emitting elements ESB as the light-emitting element ES.

The light-emitting element ESR shown in FIG. 12 includes an anode 11 (second electrode), an HTL 12, an EML 13R, an ETL 14R, and a cathode 15 (first electrode), all of which are stacked in this order when viewed from the substrate 2. In addition, the light-emitting element ESG shown in FIG. 12 includes an anode 11, the HTL 12, an EML 13G, an ETL 14G, and the cathode 15, all of which are stacked in this order when viewed from the substrate 2. The light-emitting element ESB shown in FIG. 12 includes an anode 11, the HTL 12, an EML 13B, an ETL 14B, and the cathode 15, all of which are stacked in this order when viewed from the substrate 2.

Referring to FIG. 12, the light-emitting element ESR includes the EML 13R as the EML 13 and the ETL 14R as the ETL 14. The light-emitting element ESG includes the EML 13G as the EML 13 and the ETL 14G as the ETL 14. The light-emitting element ESB includes the EML 13B as the EML 13 and the ETL 14B as the ETL 14.

The EML 13R is a red EML that emits red light and is formed in the pixels PR in an insular manner. The EML 13G is a green EML that emits red light and is formed in the pixels PG in an insular manner. The EML 13B is a blue EML that emits red light and is formed in the pixels PB in an insular manner. These EML 13R, EML 13G, and EML 13B may be either in contact with each other as shown in FIG. 12 or separated from each other.

The EML 13R contains a red light-emitting material that emits red light as a light-emitting material. The EML 13G contains a green light-emitting material that emits green light as a light-emitting material. The EML 13B contains a blue light-emitting material that emits blue light as a light-emitting material. When the light-emitting material is QDs, the identical light-emitting elements ES (identical pixels P) contain the same type of QDs. As described earlier, when the light-emitting material is QDs, the QDs enable controlling emission wavelength from the blue wavelength range to the red wavelength range by, for example, adjusting the particle diameter and composition of the QD's in a suitable manner.

Note that in the current context, blue light is, for example, light that has a peak emission wavelength in a wavelength range of from 400 nm to 500 nm, both inclusive. Green light is, for example, light that has a peak emission wavelength in a wavelength range of from 500 nm exclusive to 600 nm inclusive. Red light is light that has a peak emission wavelength in a wavelength range of from 600 nm exclusive to 780 nm inclusive.

The light-emitting element ESR includes the EML 13R as the EML 13 and the ETL 14R as the ETL 14. The light-emitting element ESG includes the EML 13G as the EML 13 and the ETL 14G as the ETL 14. The light-emitting element ESB includes the EML 13B as the EML 13 and the ETL 14B as the ETL 14.

Note that in the present embodiment, the ETLs 14 in the light-emitting elements ES may be similarly formed in an insular manner, but is preferably formed as a single piece. FIG. 12 shows an example where the ETLs 14R, the ETLs 14G, and the ETLs 14B are formed as a single piece. The ETL 14 as the first CTL can be hence formed in each pixel Pin a simple and convenient manner.

The ETL 14R includes a first area 14Ra as the first area 14a and a second area 14Rb as the second area 14b. The ETL 14G includes a first area 14Ga as the first area 14a and a second area 14Gb as the second area 14b. The ETL 14B includes a first area 14Ba as the first area 14a and a second area 14Bb as the second area 14b.

In the display device 1 in accordance with the present embodiment, the second area 14b of the ETL 14 differs in oxygen vacancy concentration for each color of the light emitted by the light-emitting elements ES. As an example, the light-emitting element ESR, the light-emitting element ESG, and the light-emitting element ESB exhibit a higher oxygen vacancy concentration in the second area 14b of the ETL 14 for a shorter peak emission wavelength of the light-emitting element ES.

Therefore, letting K1 represent the oxygen vacancy concentration in the second area 14Rb, K2 represent the oxygen vacancy concentration in the second area 14Gb, and K3 represent the oxygen vacancy concentration in the second area 14Bb, K1 to K3 satisfy an inequality, K3>K2>K1. In addition, letting K11 represent the oxygen vacancy concentration in the first area 14Ra, K12 represent the oxygen vacancy concentration in the first area 14Ga, and K13 represent the oxygen vacancy concentration in the first area 14Ba, ideally (in other words, when absolutely no light is projected), K1 to K3 satisfy an equation, K11=K12=K13. In addition, K1 to K3 and K11 to K13 have a relationship, K3>K2>K1>K11=K12=K13.

FIG. 13 is a diagram depicting, side by side, an energy band structure of each layer in the light-emitting element ESR, an energy band structure of each layer in the light-emitting element ESG, and an energy band structure of each layer in the light-emitting element ESB.

FIG. 13 shows the Fermi levels of both the anode 11 and the cathode 15. FIG. 13 further shows the bandgaps of the HTL 12, the EML 13R, the EML 13G, the EML 13B, and the unexposed ETL 14.

Referring to FIG. 13, letting EA1 represent the electron affinity of the EML 13R, the EML 13R has an electron affinity EA1 that is given by the absolute value of an energy difference between the vacuum energy level Evac and the conduction band minimum (CBM) of the EML 13R. In addition, letting EA2 represent the electron affinity of the EML 13G, the EML 13G has an electron affinity EA2 that is given by the absolute value of an energy difference between the vacuum energy level Evac and the CBM of the EML 13G. Letting EA3 represent the electron affinity of the EML 13B, the EML 13B has an electron affinity EA3 that is given by the absolute value of an energy difference between the vacuum energy level Evac and the CBM of the EML 13B.

Referring to FIG. 13, the electron affinity EA1 of the EML 13R is greater than the electron affinity EA2 of the EML 13G. In addition, the electron affinity EA2 of the EML 13G is greater than the electron affinity EA3 of the EML 13B. As described here, the electron affinities of the EML 13R, the EML 13G, and the EML 13B, as measured relative to the vacuum energy level Evac, tend to increase with an increase in the peak emission wavelength.

Generally, in the electric charge injection type of light-emitting element, the height of the electron injection barrier in injecting electrons from a first layer to a second layer that is adjacent to the first layer is given by an energy difference between the CBMs of the first layer and the second layer and corresponds to the energy obtained by subtracting the electron affinity of the second layer from the electron affinity of the first layer.

Therefore, in the light-emitting element ESR, the light-emitting element ESG, and the light-emitting element ESB, the electron injection barrier tends to be lower with an increase in the peak emission wavelength. Therefore, in the light-emitting element ESR, the light-emitting element ESG, and the light-emitting element ESB, electrons can be injected more easily with an increase in the peak emission wavelength.

Therefore, when the first CTL is the ETL 14 as shown in FIG. 12, it is preferable to increase electrical conductivity with a decrease in the peak emission wavelength and decrease electrical conductivity with an increase in the peak emission wavelength. Therefore, when the first CTL is the ETL 14 as described above, the display device 1 is preferably configured such that the oxygen vacancy concentration in the second area 14b of the ETL 14 is higher in those light-emitting elements ES which exhibit a shorter peak emission wavelength than in the other light-emitting elements ES. Therefore, when the display device 1 includes, for example, the light-emitting elements ESR, the light-emitting elements ESG, and the light-emitting elements ESB as the light-emitting elements ES as described above, K1 to K3 preferably satisfy K3>K2>K1 as described earlier. It should be understood however that the example shown in FIG. 12 is only illustrative, and the light-emitting elements ES included in the display device 1 are not necessarily limited to the light-emitting elements ESR, the light-emitting elements ESG, and the light-emitting elements ESB.

### Method for Manufacturing Display Device 1

A description is given next of a method for manufacturing the display device 1 shown in FIG. 12. The following description discusses a method for manufacturing the light-emitting elements ES in a light-emitting-element-layer-formation step (light-emitting-element-manufacturing step).

The method for manufacturing the display device 1 in accordance with the present embodiment is the same as, for example, the method for manufacturing the display device 1 in accordance with Embodiment 2, except for the following points.

In the present embodiment, a plurality of light-emitting elements ES that emit light of mutually different colors are manufactured as the plurality of light-emitting elements ES in the aforementioned light-emitting-element-layer-formation step as described above. Therefore, in the present embodiment, the EML 13R, the EML 13G, and the EML 13B are formed by coating individually in an insular manner for each pixel P in aforementioned step S4.

When these EML 13R, EML 13G, and EML 13B contain, for example, organic light-emitting materials as the light-emitting materials, the light-emitting materials are applied individually by using an FMM (fine metal mask) that has openings corresponding to the pixels P.

When these EML 13R, EML 13G, and EML 13B contain, for example, QDs as the light-emitting materials, a template in which any of the pixels PR, the pixels PG, and the pixels PB are opened is formed on the HTL 12 which is an underlayer, by using, for example, a resist. Then, a QD-dispersed solution containing QDs is applied across the entire surface from above the template and dried. Thereafter, the template is detached using a resist solvent for lift-off. This process from the formation of the template to the detachment of the template is repeated the number of times that corresponds to the number of the colors of the emitted light (3 times in the example shown in FIG. 12) to form the EML 13 of each color.

In addition, in the present embodiment, in aforementioned step S5, the ETL 14 is formed in which the oxygen vacancy concentration in the second area 14b of the ETL 14 differs for each color of the light emitted by the light-emitting elements ES. Specifically, in the present embodiment, in aforementioned step S5, the ETL 14 is formed in which the oxygen vacancy concentration in the second area 14b is higher in those light-emitting elements ES which exhibit a shorter peak emission wavelength than in the other light-emitting elements ES.

To this end, in the present embodiment, in aforementioned step S5b, either one or both of the exposure intensity and the exposure time is/are adjusted for each color of the light emitted by the light-emitting elements ES so that the oxygen vacancy concentration in the second area 14b of the ETL 14 differs for each color of the light emitted by the light-emitting elements ES. Specifically, either the exposure intensity or the exposure time is increased for those light-emitting elements ES which exhibit a shorter peak emission wavelength so that the oxygen vacancy concentration in the second area 14b of the ETL 14 is higher in those light-emitting elements ES which exhibit a shorter peak emission wavelength than in the other light-emitting elements ES. Hence, the display device 1 can be manufactured which includes such an ETL 14 that the oxygen vacancy concentration in the second area 14b is higher in those light-emitting elements ES which exhibit a shorter peak emission wavelength. As described here, the display device 1 may include an ETL 14 that exhibits an in-plane distribution of the oxygen vacancy concentration.

### Variation Example

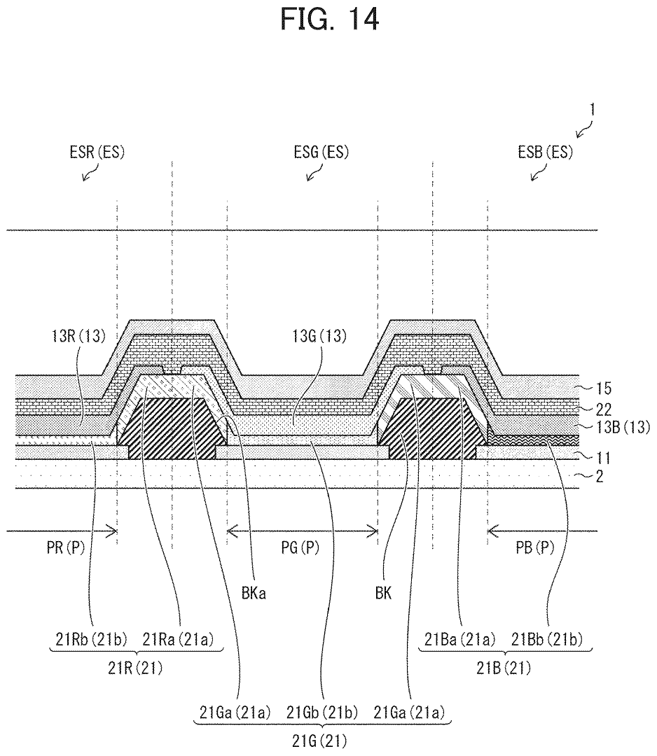

FIG. 14 is a schematic cross-sectional view of an example of a structure of a major part of the display device 1 in accordance with the present variation example.

As described in Embodiment 4, the first CTL may be an HTL. Therefore, the first electrode may be the anode 11, and the second electrode may be the cathode 15. The display device 1 shown in FIG. 14 has the same structure as the display device 1 shown in FIG. 12, except for the following points.

In the display device 1 shown in FIG. 14, the light-emitting element ESR includes the anode 11 (first electrode), an HTL 21R, the EML 13R, the ETL 22, and the cathode 15 (second electrode), all of which are stacked in this order when viewed from the substrate 2. In addition, the light-emitting element ESG shown in FIG. 14 includes the anode 11, an HTL 21G, the EML 13G, the ETL 22, and the cathode 15, all of which are stacked in this order when viewed from the substrate 2. The light-emitting element ESB shown in FIG. 14 includes the anode 11, an HTL 21B, the EML 13B, the ETL 22, and the cathode 15, all of which are stacked in this order when viewed from the substrate 2.

Note that also in the present variation example, the HTL 21 in each light-emitting element ES may be formed in an insular manner, but is preferably formed as a single piece. FIG. 14 shows an example where the HTL 21R, the HTL 21G, and the HTL 21 are formed as a single piece. The HTL 21 as the first CTL can be hence formed in each pixel Pin a simple and convenient manner.

The HTL 21R includes a first area 21Ra as the first area 21a and a second area 21Rb as the second area 21b. The HTL 21G includes a first area 21Ga as the first area 21a and a second area 21Gb as the second area 21b. The HTL 21B includes a first area 21Ba as the first area 21a and a second area 21Bb as the second area 21b.

In the display device 1 in accordance with the present variation example, the oxygen vacancy concentration in the second area 21b of the HTL 21 differs for each color of the light emitted by the light-emitting elements ES. As an example, in the light-emitting element ESR, the light-emitting element ESG, and the light-emitting element ESB, the oxygen vacancy concentration in the second area 21b of the HTL 21 is higher in those light-emitting elements ES which exhibit a longer peak emission wavelength.

Therefore, letting K21 represent the oxygen vacancy concentration in the second area 21Rb, K22 represent the oxygen vacancy concentration in the second area 21Gb, and K23 represent the oxygen vacancy concentration in the second area 21Bb, K21 to K23 satisfy an inequality, K21>K22>K23.In addition, letting K31 represent the oxygen vacancy concentration in the first area 21Ra, K32 represent the oxygen vacancy concentration in the first area 21Ga, and K33 represent the oxygen vacancy concentration in the first area 21Ba, ideally (in other words, when absolutely no light is projected), K21 to K23 satisfy an equation, K31=K32=K33.In addition, K21 to K23 and K31 to K33 have a relationship, K21>K22>K23>K31=K32=K33.

As described earlier, the electron affinities of the EML 13R, the EML 13G, and the EML 13B, as measured relative to the vacuum energy level Evac, tend to increase with an increase in the peak emission wavelength. Therefore, the electron injection barriers in the light-emitting element ESR, the light-emitting element ESG, and the light-emitting element ESB tend to decrease with an increase in the peak emission wavelength. Therefore, electrons are more readily injected to the light-emitting element ESR, the light-emitting element ESG, and the light-emitting element ESB that have a longer peak emission wavelength.

Therefore, when the first CTL is the HTL 21 as shown in FIG. 14, the electrical conductivity is preferably increased with an increase in the peak emission wavelength and decreased with a decrease in the peak emission wavelength. Therefore, in the display device 1, as described above, when the first CTL is the HTL 21, the oxygen vacancy concentration in the second area 21b of the HTL 21 is preferably higher in those light-emitting elements ES which exhibit a longer peak emission wavelength than in the other light-emitting elements ES. Therefore, as described above, when the display device 1 includes, for example, the light-emitting element ESR, the light-emitting element ESG, and the light-emitting element ESB as the light-emitting elements ES, K21 to K23 preferably satisfy K21>K22>K23 as described earlier. It should be understood however that the example shown in FIG. 14 is only illustrative, and the light-emitting elements ES included in the display device 1 are not necessarily limited to the light-emitting elements ESR, the light-emitting elements ESG, and the light-emitting elements ESB as described earlier.

### Method for Manufacturing Display Device 1

A description is given next of a method for manufacturing the display device 1 shown in FIG. 14. The following description discusses a method for manufacturing the light-emitting elements ES in a light-emitting-element-layer-formation step (light-emitting-element-manufacturing step).

The method for manufacturing the display device 1 in accordance with the present variation example is the same as, for example, the method for manufacturing the display device 1 in accordance with Embodiment 4, except for the following points.

In the present variation example, the plurality of light-emitting elements ES that emit light of mutually different colors are manufactured as the plurality of light-emitting elements ES in the aforementioned light-emitting-element-layer-formation step as described above. Therefore, also in the present variation example, as described above, the EML 13R, the EML 13G, and the EML 13B are formed by coating individually in an insular manner for each pixel P in aforementioned step S4.

In the present variation example, in aforementioned step S3′, the HTL 21 is formed in which the oxygen vacancy concentration in the second area 21b of the HTL 21 differs for each color of the light emitted by the light-emitting elements ES. Specifically, in the present variation example, in aforementioned step S3′, the HTL 21 is formed in which the oxygen vacancy concentration in the second area 21b is higher in those light-emitting elements ES which exhibit a longer peak emission wavelength than in the other light-emitting elements ES.

To this end, in the present embodiment, in aforementioned step S3′, either one or both of the exposure intensity and the exposure time is/are adjusted for each color of the light emitted by the light-emitting elements ES so that the oxygen vacancy concentration in the second area 21b of the HTL 21 differs for each color of the light emitted by the light-emitting elements ES. Specifically, either the exposure intensity or the exposure time is increased for those light-emitting elements ES which exhibit a longer peak emission wavelength so that the oxygen vacancy concentration in the second area 21b of the HTL 21 is higher in those light-emitting elements ES which exhibit a longer peak emission wavelength than in the other light-emitting elements ES. Hence, the display device 1 can be manufactured which includes such an HTL 21 that the oxygen vacancy concentration in the second area 21b is higher in those light-emitting elements ES which exhibit a longer peak emission wavelength. As described here, the display device 1 may include an HTL 21 that exhibits an in-plane distribution of the oxygen vacancy concentration.

### Variation Example 2

Note that FIGS. 12 and 14 show as an example where the display device 1 is a display device with a known structure including light-emitting elements ES with a known structure. However, the present embodiment is by no means limited to this example. Alternatively, the light-emitting element ESR, the light-emitting element ESG, the light-emitting element ESB, and the display device 1 may have an inverted structure as described earlier. In any case, the present embodiment can provide the light-emitting element ES and the display device 1 in both of which the luminous efficiency such as the EQE is high and also provide a method for manufacturing the light-emitting element ES and a method for manufacturing the display device 1 that enable the manufacture of the light-emitting element ES and the display device 1.

### Embodiment 6

As described earlier, not only the EML 13, but also either the HTL 12 or the HTL 21 and either the ETL 14 or the ETL 22 may be formed in an insular manner for each pixel P.

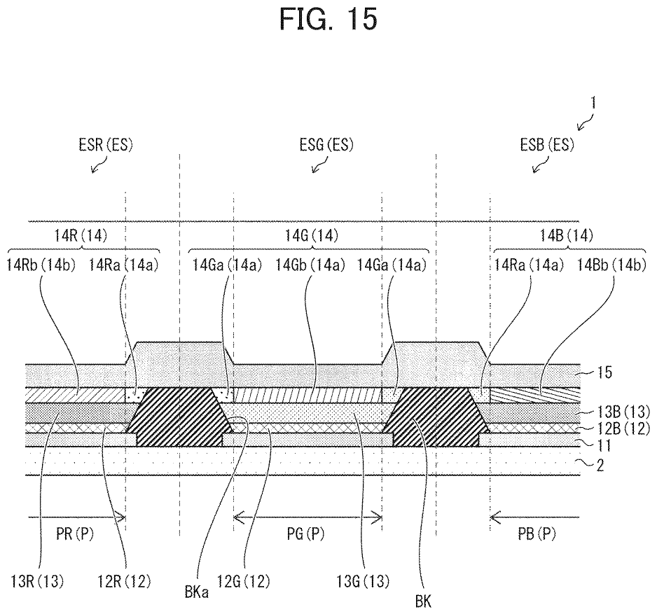

FIG. 15 is a schematic cross-sectional view of an example of a structure of a major part of the display device 1 in accordance with the present embodiment.

The display device 1 shown in FIG. 15 has the same structure as, for example, the display device 1 shown in FIG. 12, except for the following points.

The light-emitting element ESR shown in FIG. 15 includes the anode 11 (second electrode), an HTL 12R, the EML 13R, the ETL 14R, and the cathode 15 (first electrode), all of which are stacked in this order when viewed from the substrate 2. In addition, the light-emitting element ESG shown in FIG. 15 includes the anode 11, an HTL 12G, the EML 13G, the ETL 14G, and the cathode 15, all of which are stacked in this order when viewed from the substrate 2. The light-emitting element ESB shown in FIG. 15 includes the anode 11, the HTL 12B, the EML 13B, the ETL 14B, and the cathode 15, all of which are stacked in this order when viewed from the substrate 2.

Referring to FIG. 15, in the display device 1 in accordance with the present embodiment, each layer other than the cathode 15 in each light-emitting element ES is formed in an insular manner. Therefore, in the present embodiment, the ETL 14 as the first CTL in the plurality of light-emitting elements ES is provided for each light-emitting element ES.

In the present embodiment, in step S3, the HTL 12 is formed in an insular manner for each light-emitting element ES. In addition, in the present embodiment, in step S5a, the ETL 14 is formed in an insular manner for each light-emitting element ES. Except for these points, the method for manufacturing the display device 1 shown in FIG. 15 is the same as the method for manufacturing the display device 1 shown in FIG. 12.

When the ETL 14 is formed in an insular manner for each light-emitting element ES as described here, the ETL 14R, the ETL 14G, and the ETL 14B may be made of the same material and may be made of different materials. When the ETL 14 is formed in an insular manner for each light-emitting element ES as described here, desirable electron transport materials can be used for each color of emitted light.

Similarly, when the HTL 12 is formed in an insular manner for each light-emitting element ES, the HTL 12R, the HTL 12G, and an HTL 12B may be made of the same material and may be made of different materials. When the HTL 12 is formed in an insular manner for each light-emitting element ES as described here, desirable hole transport materials can be used for each color of emitted light.

These insular ETL 14 and HTL 12 can be formed by, for example, inkjet printing.

As described earlier, the films formed in the vicinity of the bank BK, which covers the edge of the pixel electrode that is an underlying-layer electrode, are susceptible to defects, and it is difficult to form uniform films in the vicinity of the bank BK. The luminous efficiency is lower in these defective film-formed regions than in the normal film-formed regions. Therefore, in the present embodiment, the defective film-formed region in the vicinity of the bank BK in the ETL 14 formed in an insular manner is designated as the first area 14a, and the normal film-formed region located in a central portion, of the pixel electrode, that provides a central pixel portion, in other words, the region other than the defective film-formed region, is designated as the second area 14b, as shown in FIG. 15. Hence, in each light-emitting element ES, the excess current flowing in the region that is a defective film-formed region in the vicinity of the bank BK, that is also the edge of the pixel electrode, and that has a low luminous efficiency can be relatively reduced, and this region can be restrained from emitting light. Therefore, the present embodiment can similarly provide the light-emitting element ES and the display device 1 in both of which the excess current is relatively reduced and the luminous efficiency such as the EQE is high and also provide a method for manufacturing the light-emitting element ES and a method for manufacturing the display device 1 that enable the manufacture of the light-emitting element ES and the display device 1.

### Variation Example

Note that FIG. 15 shows an example where in the light-emitting elements ES in the display device 1 shown in FIG. 12, each layer, including the ETL 14, other than the cathode 15 is formed in an insular manner. However, the present embodiment is by no means limited to this example. Alternatively, each layer other than the common electrode which is an overlying-layer electrode may be formed in an insular manner in the light-emitting elements ES in each display device 1 described in Embodiments 1 to 5 other than the display device 1 shown in FIG. 12, for example, the display devices 1 shown in, for example, FIGS. 7, 8, 10, and 14. In any case, the first CTL may be formed in an insular manner, and even when the first CTL is formed in an insular manner as described here, the luminous efficiency can be improved by restraining the defective film-formed regions from emitting light as described above.

The present disclosure is not limited to the description of the embodiments above and may be altered within the scope of the claims. Embodiments based on a proper combination of technical means disclosed in different embodiments are encompassed in the technical scope of the present disclosure. Furthermore, new technical features can be created by combining different technical means disclosed in the embodiments.

1. A light-emitting element comprising:
a first electrode and a second electrode;
a light-emitting layer provided between the first electrode and the second electrode; and
a charge transport layer provided between the first electrode and the light-emitting layer, wherein
the charge transport layer contains a metal oxide and includes a first area and a second area that has an oxygen vacancy concentration higher than an oxygen vacancy concentration of the first area.

2. The light-emitting element according to claim 1, further comprising a light-emitting region and a non-light-emitting region, wherein the second area is provided in a region, of the charge transport layer, that corresponds to at least a part of the light-emitting region.

3. The light-emitting element according to claim 2, wherein the second area is provided in a region, of the charge transport layer, that corresponds to a part of the light-emitting region other than an end of the light-emitting region.

4. The light-emitting element according to claim 1, further comprising:
a light-emitting region and a non-light-emitting region, wherein the first area is provided in a region, of the charge transport layer, that corresponds to at least a part of the non-light-emitting region.

5. The light-emitting element according to claim 1, wherein the metal oxide contains at least one selected from the group consisting of zinc oxide, aluminum zinc oxide, lithium zinc oxide, magnesium zinc oxide, nickel oxide, copper oxide, vanadium oxide, titanium oxide, molybdenum oxide, and tungsten oxide.

6. A display device comprising:
a plurality of pixels, each including the light-emitting element according to claim 1.

7. The display device according to claim 6, wherein a plurality of charge transport layers, including the charge transport layer, in a plurality of light-emitting elements, including the light-emitting element, is formed as a single piece.

8. The display device according to claim 7, wherein
the first electrode is a pixel electrode provided for each of the plurality of pixels,
the second electrode is a common electrode commonly provided to the plurality of pixels, and
in each of the plurality of light-emitting elements, the charge transport layer is provided closer to the pixel electrode than the light-emitting layer is.

9. The display device according to claim 6, wherein a plurality of charge transport layers, including the charge transport layer in a plurality of light-emitting elements, including the light-emitting element, is provided individually for each of the plurality of light-emitting elements.

10. The display device according to claim 6, wherein
a plurality of light-emitting elements, including the light-emitting element, includes a plurality of first light-emitting elements that emits light of mutually different colors, and
oxygen vacancy concentrations in second areas of charge transport layers of the plurality of light-emitting elements differ for each color of the light emitted by the plurality of first light-emitting elements.

11. The display device according to claim 10, wherein
the charge transport layers are electron transport layers, and
the oxygen vacancy concentrations in the second areas of the charge transport layers are higher in first light-emitting elements, among the plurality of first light-emitting elements, which exhibit a shorter peak emission wavelength than in a remainder of the plurality of first light-emitting elements.

12. The display device according to claim 6, wherein
a plurality of charge transport layers, including the charge transport layer, is electron transport layers, and
the metal oxide contains one or both of a zinc oxide and a magnesium zinc oxide.

13. The display device according to claim 10, wherein
a plurality of charge transport layers, including the charge transport layer, is hole transport layers, and
oxygen vacancy concentrations in second areas of the plurality of charge transport layers are higher in first light-emitting elements, among the plurality of first light-emitting elements, which exhibit a longer peak emission wavelength than in a remainder of the plurality of first light-emitting elements.

14. A method for manufacturing a light-emitting element including: a first electrode and a second electrode; a light-emitting layer provided between the first electrode and the second electrode; and a charge transport layer provided between the first electrode and the light-emitting layer, the method comprising:
forming a charge transport layer containing a metal oxide, as the charge transport layer; and
forming, in a part of the charge transport layer, a second area that has an oxygen vacancy concentration higher than an oxygen vacancy concentration of a first area that is a non-exposed area of the charge transport layer, by exposing the part of the charge transport layer to light to increase oxygen vacancies in an exposed area.

15. The method according to claim 14, wherein
the light-emitting element has a light-emitting region and a non-light-emitting region, and
forming the second area comprises exposing, to light, a region, of the charge transport layer, that corresponds to at least one part of the light-emitting region to provide the second area in the region, of the charge transport layer, that corresponds to the at least one part of the light-emitting region.

16. The method according to claim 14, wherein
the light-emitting element has a light-emitting region and a non-light-emitting region, and
forming the second area comprises exposing, to light, a region, of the charge transport layer, that corresponds to at least one part of the non-light-emitting region to provide the first area in the region, of the charge transport layer, that corresponds to the at least one part of the non-light-emitting region.

17. A method for manufacturing a display device including a plurality of pixels each including a light-emitting element, the method comprising:
manufacturing a plurality of light-emitting elements, including the light-emitting element, by the method according to claim 14.

18. The method according to claim 17, wherein forming the charge transport layer comprises forming a plurality of charge transport layers, including the charge transport layer, in a plurality of light-emitting elements, including the light-emitting element, as a single piece.

19. The method according to claim 18, wherein manufacturing the plurality of light-emitting elements comprises:
forming the first electrode before forming the charge transport layer; and
forming the light-emitting layer after forming the second area.

20. The method according to claim 17, wherein forming the charge transport layer comprises forming a plurality of charge transport layers, including the charge transport layer, in a plurality of light-emitting elements individually for each of the plurality of light-emitting elements.

21.-25. (canceled)
